(19) United States
(12) Patent Application Publication
(10) Pub. No.: US 2010/0048025 A1
(43) Pub. Date: Feb. 25, 2010

(54) NANOSTRUCTURES AND NANOSTRUCTURE FABRICATION

(75) Inventor: Sunghoon Kwon, Seoul (KR)

Correspondence Address: KNOBBE MARTENS OLSON & BEAR LLP, 2040 MAIN STREET, FOURTEENTH FLOOR, IRVINE, CA, 92614, US

(73) Assignee: Seoul National University Industry Foundation, Seoul (KR)

(21) Appl. No.: 12/197,997

(22) Filed: Aug. 25, 2008

(51) Int. Cl. H01L 21/3205

(52) U.S. Cl. 438/703; 257/E21.297

(57) ABSTRACT

Nanostructure and techniques for fabricating nanostructures are provided. In one embodiment, nanostructures may be formed by providing a Silicon-on-Insulator (SOI) substrate, forming a pattern on the SOI substrate, disposing a conformal layer over the pattern, etching the conformal layer, except for a sidewall portion, removing the pattern, transferring the sidewall pattern to the silicon layer of the SOI substrate to form the nanostructure, and releasing the nanostructure.

### TECHNICAL FIELD

The present disclosure relates generally to nanostructures.

### BACKGROUND

Recent developments in semiconductor technology have resulted in reduced size of electronic component devices, particularly the width of wires in the devices. As a result, the importance of nanowires for electrically connecting devices is ever-increasing. Nanowires have a wide range of applications depending on relevant substances. For example, nanowires have been used for devices for emitting/receiving light (optical usage). Furthermore, nanowires have been added to composite materials (mechanical usage). Although nanowires can be potentially used in many fields, typical nanowires are limited with regard to shape and size.

### BRIEF DESCRIPTION OF THE DRAWINGS

FIG. 1A is a side cross-sectional view of an illustrative embodiment of an SOI substrate.

FIG. 1B is a side cross-sectional view of an illustrative embodiment of a method of forming the SOI substrate of FIG. 1A.

FIG. 2 is a side cross-sectional view of an illustrative embodiment of an SOI substrate on which an oxide layer is disposed.

FIGS. 3A and 3B are side cross-sectional views of an illustrative embodiment of an SOI substrate on which a polysilicon pattern is formed.

FIG. 4 is a side cross-sectional view of an illustrative embodiment of an SOI substrate on which a second oxide layer is disposed.

FIG. 5 is a side cross-sectional view of an illustrative embodiment of an SOI substrate on which a second oxide layer is etched.

FIG. 6 is a side cross-sectional view of an illustrative embodiment of an SOI substrate in which a polysilicon pattern is removed.

FIG. 7 is a side cross-sectional view of an illustrative embodiment of a substrate on which a nanostructure is formed.

FIG. 8 is a side cross-sectional view of an illustrative embodiment of a substrate on which a first oxide layer is etched.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It will be readily understood that the components of the present disclosure, as generally described herein, and illustrated in the Figures, may be arranged, substituted, combined, and designed in a wide variety of different configurations, all of which are explicitly contemplated and make part of this disclosure.

Techniques for fabricating a nanostructure having a desired shape and size with high throughput and low cost, and a nanostructure fabricated by the same are provided.

In one embodiment, a method for fabricating a nanostructure may include forming a Silicon-on-Insulator (SOI) substrate including a silicon wafer, a first oxide layer, and a silicon layer. The method may also include forming a polysilicon pattern on the SOI substrate, depositing a second oxide layer on the SOI substrate on which the polysilicon pattern is formed, and etching the second oxide layer formed on the SOI substrate and the polysilicon pattern, except for the second oxide layer formed on a sidewall of the polysilicon pattern. The method may further include removing the polysilicon pattern, transferring an oxide sidewall to the silicon layer of the SOI substrate in order to fabricate the nanostructure, and etching the first oxide layer in order to release the nanostructure.

In other embodiments, the method may further include forming a protection layer on the SOI substrate prior to forming the polysilicon pattern. The first oxide layer may be formed on the silicon wafer, the silicon layer may be formed on the first oxide layer, and the protection layer may be formed on the silicon layer. The protection layer may be formed by depositing a silicon oxide on the SOI substrate by a thermal oxidation, a chemical Vapor Deposition (CVD), or a sputtering. The polysilicon pattern may be formed by depositing the polysilicon layer on the SOI substrate and patterning the polysilicon layer by an optical lithography to form the polysilicon pattern such that the nanostructure has a desired top-view.

The method may further include removing remaining polymer generated by the optical lithography. The second oxide layer may be deposited on the SOI substrate by depositing a silicon oxide on the polysilicon pattern by CVD. The second oxide layer may be etched by using an anisotropic plasma etching. The polysilicon pattern may be removed by etching the polysilicon pattern by a wet etching or a plasma etching. The oxide sidewall may be transferred to the silicon layer of the SOI substrate by a plasma etching. The first oxide layer may be etched by a wet etching. The first oxide layer and the second oxide layer may include SiO₂, respectively.

In another embodiment, a method for fabricating a nanostructure may include forming an SOI substrate including a buried first sacrificial layer and a silicon layer, forming a second sacrificial layer on the SOI substrate, patterning the second sacrificial layer, and forming a conformal layer on the patterned second sacrificial layer. The method may also include etching the conformal layer, except for a portion of the conformal layer formed on a sidewall of the patterned second sacrificial layer, removing the patterned second sacrificial layer from the SOI substrate, transferring the remaining conformal layer to the silicon layer of the SOI substrate in order to fabricate a nanostructure, and etching the buried first sacrificial layer in order to release the nanostructure.

In some embodiments, the SOI substrate may further include a silicon wafer. The first sacrificial layer may be formed on the silicon wafer, and the silicon layer may be formed on the first sacrificial layer.

The method may further include forming a protection layer on the silicon layer of the SOI substrate prior to forming the second sacrificial layer. The second sacrificial layer may be formed by depositing a polysilicon layer on the SOI substrate. The second sacrificial layer may be patterned by patterning the polysilicon layer with an optical lithography to form the patterned second sacrificial layer such that the nanostructure has a desired structure, for example, a top shape of the nanostructure.

The method may further include removing a remaining polymer generated by the optical lithography after patterning the second sacrificial layer. The conformal layer may be deposited on the patterned second sacrificial layer by depositing a silicon oxide on the patterned second sacrificial layer by CVD. The conformal layer may be etched by an anisotropic plasma etching. The patterned second sacrificial layer may be removed by etching the second sacrificial layer by a wet etching or a plasma etching. The remaining conformal layer may be transferred to the silicon layer of the SOI substrate by plasma etching. The buried first sacrificial layer may be etched by a wet etching. The first sacrificial layer and the second sacrificial layer may include SiO₂, respectively. In a further embodiment, a nanostructure fabricated by a method stated above may be provided.

In one embodiment, a solar cell, a textile, and a bio sensor may include the nanostructure described above. The method according to one embodiment may fabricate the nanostructure having a desired shape and size with high throughput and low cost.

In the following description, when it is said that a layer or substrate is “on” or “above” another element, it will be understood that the layer or substrate is positioned either directly on or above said another element, or on or above said another element with one or more elements positioned between them.

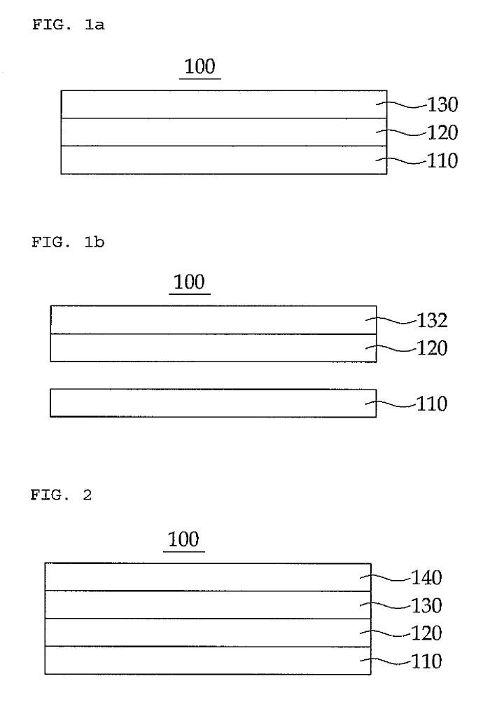

Hereinafter, an illustrative embodiment of a method for fabricating a nanostructure according to one embodiment will be described with reference to FIGS. 1A to 8.

FIG. 1A is a side cross-sectional view of an illustrative Silicon-on-Insulator (SOI) substrate 100 according to one embodiment. SOI substrate 100 may include a silicon wafer 110, a first oxide layer 120, and a silicon layer 130. SOI substrate 100 may be fabricated by a Separation by Implanted Oxygen (SIMOX) method. In one example of the SOI substrate, silicon wafer 110 may have a thickness of approximately 525 micrometers, and first oxide layer 120 may be comprised of SiO₂ and have a thickness of approximately 1 micrometer. Alternatively, first oxide layer 120 may be used as a first sacrificial layer in a subsequent etching process, as described below.

In another embodiment, SOI substrate 100 may be formed by fusing a silicon layer 132 having first oxide layer 120 to a separate silicon substrate 110. As shown in FIG. 1B, first oxide layer 120 may be formed on silicon layer 132, and silicon layer 132 and first oxide layer 120 may be fused with a separate silicon wafer 110. In various examples, silicon layer 132 and first oxide layer 120 may be a Si substrate having an oxide surface, a Si substrate having first oxide layer 120 formed thereon (for example, by Chemical Vapor Deposition (CVD)), or a multilayer structure in which a Si layer may be formed. The multilayer structure may be formed by, for example, forming porousness on a surface of a Si substrate or in an entire Si substrate, expitaxially growing a Si single crystal thin film on the porousness structure of the Si substrate, and oxidizing a surface of the silicon single crystal thin film. Alternatively, the multilayer structure may be formed, for example, by epitaxially growing the Si single crystal thin film on a sapphire substrate and oxidizing the surface of the Si single crystal thin film.

Then, silicon layer 132 may be fused with silicon wafer 110. For example, a hydrophobic treatment may be performed on the top surface of silicon wafer 110. A hydrophobic or hydrophilic treatment may be performed on a bottom surface of silicon layer 132 and oxide layer 120. The treated surfaces may be brought into contact and fused or pasted together. The pasted surface may be heated at approximately 900 degrees Celsius or higher. The heating may be performed, for example, for several hours at around 800 degrees Celsius or for several minutes to several tens of minutes at around 1200 degrees Celsius. Silicon layer 132 of the resulting substrate may be further treated to be a thin layer. A grinding or etching may be used to make silicon layer 132 a desired thickness, for example, approximately 100 nanometers.

After the SOI substrate 100 is prepared according to a method described above, a protection layer 140 may be formed on the silicon layer 130 or 132, as shown in FIG. 2. Protection layer 140 may include any material that may protect the SOI substrate 100 from a following etching process, such as, for example, an oxide. Protection layer 140 may be formed on silicon layer 130 by a thermal oxidation, a CVD, or a sputtering.

In one example, protection layer 140 may be grown in a water stream and oxygen at approximately 850 degrees Celsius. The thickness of protection layer 140 may be determined by considering various factors. One factor may be that protection layer 140 may be thin enough to minimize pattern broadening in forming a hard mask for a following silicon etching. Another factor may be that protection layer 140 may be thick enough to protect the SOI substrate 100 during a following etching of a polysilicon layer. For example, protection layer 140 may have a thickness of approximately 50 nanometers. If the etching of protection layer 140 does not reach the SOI substrate 100, the protection layer 140 may not be required for protecting the SOI substrate 100. Therefore, the protection layer 140 is optional.

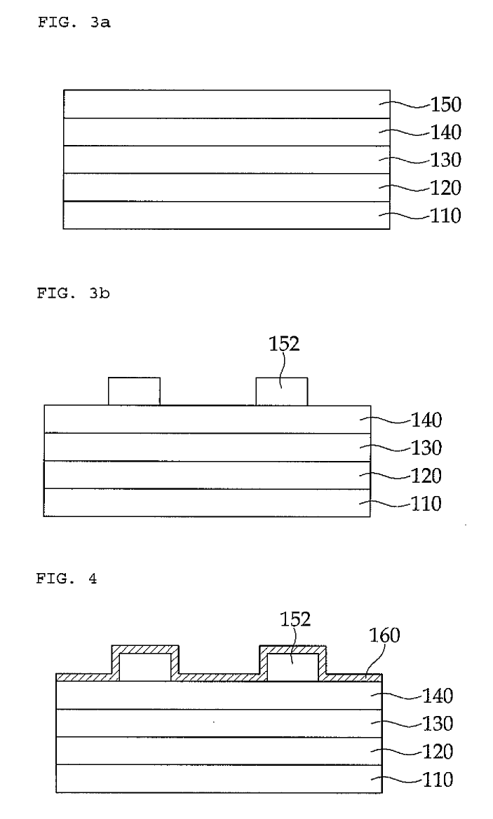

As shown in FIG. 3A, a polysilicon layer 150 may be deposited on protection layer 140. If no protection layer 140 exists, polysilicon layer 150 may be directly deposited on silicon layer 130. In an example, polysilicon layer 150 may be deposited on protection layer 140 or silicon layer 130 by a low-pressure CVD using SiH₄ at approximately 600 degrees Celsius.

As shown in FIG. 3B, polysilicon layer 150 may be patterned by an optical lithography. In an example, the patterning may include a photoresist (not shown) coated on polysilicon layer 150. A desired pattern may be transferred to the photoresist layer, and the pattern may be transferred from the photoresist layer to polysilicon layer 150 by plasma etching. As a result, a polysilicon pattern 152 may be formed on protection layer 140. Polysilicon pattern 152 may be used as a second sacrificial layer in a subsequent etching step for fabricating a nanostructure, as will be described later in detail. In an example, the etching may be conducted with the conditions of about 50 sccm Cl₂, about 150 sccm Hbr, a pressure about 15 mTorr, an electrode temperature about 50 degrees Celsius, about 300 W top electrode power, and about 150 W bottom electrode power with about −160V bias, but it is not limited thereto.

In an embodiment, the remaining polymer generated by the optical lithography may be removed. For example, SOI substrate 100 on which the protection layer 140 and the polysilicon pattern 152 may be formed may be dipped in (100:1) HF for about 10 seconds. Then, the photoresist may be stripped with oxygen plasma, and the SOI substrate 100 may be dipped into [(4:1) H2SO4: H2O2] piranha bath which is treated at about 120 degrees Celsius. As a result, the remaining polymer may be removed.

As shown in FIG. 4, a second oxide layer 160 may be deposited as a conformal layer on the SOI substrate and over protection layer 140 and polysilicon pattern 152. If protection layer 140 is not formed, second oxide layer 160 may be deposited directly on SOI substrate 100 and polysilicon pattern 152. The conformal layer may be a layer having a thickness of approximately nanometer—1 micrometer. The thickness of the conformal layer may be determined based on a desired final size of the nanostructure. The conformal layer may include a material having an etching property different from that of polysilicon layer 150. According to one embodiment, second oxide layer 160 may include silicon oxide, but is not limited thereto. Second oxide layer 160 including SiO₂ may be deposited by a low-pressure CVD. The conditions of the low-pressure CVD may be about 5 sccm SiH₄ and about 70 sccm O₂ at about 450 degrees Celsius, but are not limited thereto. The thickness of second oxide layer 160 on a side surface of polysilicon pattern 152 may determine a size of the nanostructure to be fabricated.

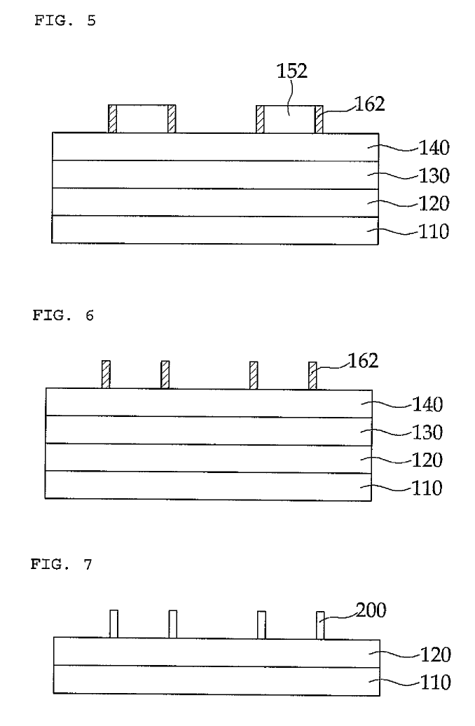

As shown in FIG. 5, second oxide layer 160 may etched in one direction to expose a top surface of polysilicon pattern 152 and protection layer 140 except for the portion of second oxide layer 160 formed on a sidewall 162 of the polysilicon pattern 152. In one example, the etching may be conducted by an anisotropic plasma etching. The conditions of the anisotropic etch may be about 100 scam CF₄, pressure about 13 mTorr, about 200 W top electrode power, and about 40 W bottom electrode power with a bias of about −80 V, but are not limited thereto.

As shown in FIG. 6, polysilicon pattern 152 may be removed. Polysilicon pattern 152 may be used as a second sacrificial layer, and may leave oxide sidewall 162 on protection layer 140. In some examples, the removal of the polysilicon pattern 152 may be implemented through either a wet etching or a plasma etching. The wet etching may be conducted in 1:2 W KOH aqueous solution at about 80 degrees Celsius, but is not limited thereto. The plasma etching may be conducted with conditions substantially the same as those of the plasma etching when forming polysilicon pattern 152, as discussed above.

As shown in FIG. 7, oxide sidewall 162 may be transferred to silicon layer 130 of the SOI substrate so as to fabricate a nanostructure 200. The transfer may be implemented, for example, as follows. Oxide sidewall 162 may be transferred to protection layer 140 by a plasma etching. The conditions of the plasma etching may be about 1000 sccm CF₄, pressure about 13 mTorr, about 200 W top electrode power, and about 40 W bottom electrode power, but are not limited thereto. Alternatively, where protection layer 140 does not exist, the first step may not be required. The transferred pattern may be transferred to silicon layer 130 by a plasma etching. The conditions of the plasma ethching may be about 50 sccm Cl₂, about 150 sccm HBr, pressure about 15 mTorr, about 300 W top electrode power, and about 150 W bottom electrode power at electrode temperature about 50 degrees Celsius, but are not limited thereto.

Nanostructure 200 may be originated from the portion formed on the side surface of polysilicon pattern 152 in second oxide layer 160, that is, sidewall 162 of polysilicon pattern 152. Thus, the top view structure of nanostructure 200 may be determined by the shape of the polysilicon pattern 152. Further, a width of nanostructure 200 may be determined by a width of oxide sidewall 162 and a height of nanostructure 200 may be determined by a thickness of silicon layer 130 of the SOI substrate. Therefore, it may be possible to control the shape, width, and height of nanostructure 200 through controlling the shape of polysilicon pattern 152, the thickness of the oxide deposited on the sidewall of polysilicon pattern 152, and the thickness of silicon layer 130 of the SOI substrate.

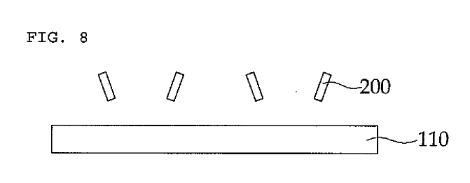

As shown in FIG. 8, nanostructure 200 may be released from the SOI substrate. In one embodiment, first oxide layer 120 included in the SOI substrate may be used as the first sacrificial layer, as described above, so as to obtain nanostructure 200 from the SOI substrate. For example, first oxide layer 120 of the SOI substrate may be removed by an etching so that nanostructure 200 formed on first oxide layer 120 may be released. The etching, for example, may be wet etching. In this case, nanostructure 200 may be released and floated in the etching solution.

The nanostructures fabricated according to the above described embodiments may be applied to a small-sized structure, such as solar cells, textiles, or bio sensors. In some embodiments, a solar cell may be manufactured in the form of a plastic cover or paint using the described nanostructures. The solar cell may be used as a coating agent so that it may be coated anywhere that may be exposed to sunlight. In other embodiments, the described nanostructures may be used for manufacturing a textile. For example, the nanostructure may be fabricated in the form of a cobweb. The textile having such nanostructure may be thin and may have resistant properties. In other embodiments, the nanostructures as described may be used in a nano-bio sensor which may be directly inserted in a sensing object. As used herein, such applications are introduced, but the present disclosure is not limited thereto.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A method for fabricating a nanostructure, comprising:
providing a Silicon-on-Insulator (SOI) substrate including a silicon wafer, a first oxide layer, and a silicon layer;
disposing a polysilicon pattern on the SOI substrate;
disposing a second oxide layer on the SOI substrate and the polysilicon pattern;
removing a portion of the second oxide layer to form a sidewall structure adjacent to the polysilicon pattern;
removing the polysilicon pattern;
transferring an oxide sidewall pattern of the sidewall structure to the silicon layer of the SOI substrate to form a nanostructure; and
removing at least a portion of the first oxide layer in order to release the nanostructure.

2. The method of claim 1, further comprising:
forming a protection layer on the SOI substrate prior to forming the polysilicon pattern, wherein the first oxide layer is on the silicon wafer, the silicon layer is on the first oxide layer, and the protection layer is formed on the silicon layer.

3. The method of claim 2, wherein forming the protection layer comprises depositing a silicon oxide on the SOI substrate by at least one of a thermal oxidation, a Chemical Vapor Deposition (CVD), or a sputtering.

4. The method of claim 1, wherein said disposing the polysilicon pattern comprises:
depositing a polysilicon layer on the SOT substrate; and
patterning the polysilicon layer by an optical lithography to form the polysilicon pattern such that the nanostructure has desired structure.

5. The method of claim 4, wherein said disposing the polysilicon pattern further comprises removing a remaining polymer generated by the optical lithography.

6. The method of claim 1, wherein said disposing the second oxide layer comprises depositing a silicon oxide by CVD.

7. The method of claim 1, wherein said removing the portion of the second oxide layer comprises etching the second oxide layer by an anisotropic plasma etching.

8. The method of claim 1, wherein said removing the polysilicon pattern comprises etching the polysilicon pattern by at least one of a wet etching or a plasma etching.

9. The method of claim 1, wherein said transferring the oxide sidewall pattern comprises a plasma etching.

10. The method of claim 1, wherein said removing at least the portion of the first oxide layer comprises etching the first oxide layer by a wet etching.

11. The method of claim 1, wherein the first oxide layer and the second oxide layer include SiO₂.

12. A method for fabricating a nanostructure, comprising:
providing an SOI substrate including a first sacrificial layer and a silicon layer;
disposing a second sacrificial layer on the SOI substrate;
patterning the second sacrificial layer to form a patterned second sacrificial layer;
disposing a conformal layer on the patterned second sacrificial layer;
removing a portion of the conformal layer to form a sidewall structure adjacent to the patterned second sacrificial layer;
removing the patterned second sacrificial layer;
transferring a sidewall structure pattern of the sidewall structure to the silicon layer of the SOI substrate to form a nanostructure; and
removing at least a portion of the first sacrificial layer to release the nanostructure.

13. The method of claim 12, wherein the SOI substrate further comprises a silicon wafer, wherein the first sacrificial layer is on the silicon wafer and the silicon layer is on the first sacrificial layer.

14. The method of claim 13, further comprising:
forming a protection layer on the silicon layer prior to forming the second sacrificial layer.

15. The method of claim 12, wherein disposing said second sacrificial layer comprises depositing a polysilicon layer on the SOI substrate, and patterning the second sacrificial layer comprises patterning the polysilicon layer an by optical lithography to form the patterned second sacrificial layer such that the nanostructure has desired structure.

16. The method of claim 15, further comprising:
removing a remaining polymer generated by the optical lithography after patterning the second sacrificial layer.

17. The method of claim 12, wherein said disposing the conformal layer comprises depositing a silicon oxide by CVD.

18. The method of claim 12, wherein said removing a portion of the conformal layer comprises etching the conformal layer by an anisotropic plasma etching.

19. The method of claim 12, wherein said removing the patterned second sacrificial layer comprises etching the second sacrificial layer by at least one of a wet etching or a plasma etching.

20. The method of claim 12, wherein said transferring the sidewall structure pattern comprises a plasma etching.

21. The method of claim 12, wherein said removing the at least a portion of the first sacrificial layer comprises a wet etching.

22. The method of claim 12, wherein the first sacrificial layer and the second sacrificial layer include SiO₂.
